(19) United States
(12) Patent Application Publication
(10) Pub. No.: US 2025/0253275 A1
(43) Pub. Date: Aug. 7, 2025

(54) SEMICONDUCTOR DEVICE AND MANUFACTURING METHOD THEREOF

(71) Applicants: nD-HI Technologies Lab, Inc., Taipei City (TW); ETRON TECHNOLOGY, INC., Hsinchu (TW)

(72) Inventors: Ho-Ming TONG, Taipei City (TW); Chao-Chun LU, Hsinchu (TW)

(73) Assignees: nD-HI Technologies Lab, Inc., Taipei City (TW); ETRON TECHNOLOGY, INC., Hsinchu (TW)

(21) Appl. No.: 19/046,823

(22) Filed: Feb. 6, 2025

Related U.S. Application Data
(60) Provisional application No. 63/550,617, filed on Feb. 7, 2024.

(51) Int. Cl. H01L 23/00; H01L 23/367; H01L 25/065

(52) U.S. Cl. CPC H01L 24/08; H01L 24/05; H01L 24/80; H01L 25/0657; H01L 23/3672; H01L 24/13; H01L 24/16; H01L 24/32; H01L 24/73; H01L 2224/05644; H01L 2224/08145; H01L 2224/13147; H01L 2224/16225; H01L 2224/32225; H01L 2224/73204; H01L 2224/80013; H01L 2224/80345; H01L 2224/80357; H01L 2224/80895; H01L 2224/80896; H01L 2924/1815

(57) ABSTRACT

A semiconductor device includes a first semiconductor component and a second semiconductor component. The first semiconductor component includes a first substrate, a first dielectric layer and a first pad, wherein the first dielectric layer is disposed over the first substrate and has a first opening, and the first pad is disposed in the first opening. The second semiconductor component includes a second substrate, a second dielectric layer and a second pad, wherein the second dielectric layer is disposed over the second substrate and has a second opening, and the second pad is disposed in the second opening. The first dielectric layer is contact with the second dielectric layer, and the first pad is contact with the second pad.

This application claims the benefit of U.S. provisional application Ser. No. 63/550,617, filed Feb. 7, 2024, the subject matter of which is incorporated herein by reference.

### BACKGROUND OF THE INVENTION

### Field of the Invention

The invention relates in general to a semiconductor device and a manufacturing method thereof.

### Description of the Related Art

As semiconductor technology further advances, stacked semiconductor devices such as three-dimensional integrated circuits have become an effective alternative to further reduce the physical size of semiconductor devices. In stacked semiconductor devices, active circuits such as logic, memory, processor circuit, and the like are fabricated on separate semiconductor wafers. However, the stacked semiconductor device generally has a greater thickness.

Thus, how to reduce the thickness of semiconductor devices is one of the goals of industry players in this technical field.

### SUMMARY OF THE INVENTION

According to an embodiment of the present invention, a semiconductor device is provided. The semiconductor device includes a first semiconductor component and a second semiconductor component. The first semiconductor component includes a first substrate, a first dielectric layer and a first pad, wherein the first dielectric layer is disposed over the first substrate and has a first opening, and the first pad is disposed in the first opening. The second semiconductor component includes a second substrate, a second dielectric layer and a second pad, wherein the second dielectric layer is disposed over the second substrate and has a second opening, and the second pad is disposed in the second opening. The first dielectric layer is contact with the second dielectric layer, and the first pad is contact with the second pad.

According to another embodiment of the present invention, a manufacturing method for a semiconductor device is provided. The manufacturing method includes the following steps: providing a first semiconductor component, wherein the first semiconductor component includes a first substrate, a first dielectric layer and a first pad, the first dielectric layer is disposed over the first substrate and has a first opening, and the first pad is disposed in the first opening; providing a second semiconductor component, wherein the second semiconductor component includes a second substrate, a second dielectric layer and a second pad, the second dielectric layer is disposed over the second substrate and has a second opening, and the second pad is disposed in the second opening; activating the first dielectric layer and the first pad of the first semiconductor component and the second dielectric layer and the second pad of the second semiconductor component; and connecting the first semiconductor component with the second semiconductor component, wherein the first dielectric layer is contact with the second dielectric layer, and the first pad is contact with the second pad.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a schematic diagram of a semiconductor device according to an embodiment of the present invention;

FIG. 2 illustrates a schematic diagram of a semiconductor device according to another embodiment of the present invention;

FIG. 3 illustrates a schematic diagram of a semiconductor device according to another embodiment of the present invention;

FIG. 4 illustrates a schematic diagram of a semiconductor device according to another embodiment of the present invention;

FIG. 5 illustrates a schematic diagram of a semiconductor device according to another embodiment of the present invention;

FIG. 6 illustrates a schematic diagram of a semiconductor device according to another embodiment of the present invention;

FIGS. 7A to 7K illustrate schematic diagrams of a manufacturing method of the semiconductor device in FIG. 1;

FIG. 8 illustrates a schematic diagram of a process of a manufacturing method of the semiconductor device in FIG. 2;

FIG. 9 illustrates a schematic diagram of a process of a manufacturing method of the semiconductor device in FIG. 3; and

FIGS. 10A to 10L illustrate schematic diagrams of a manufacturing method of the semiconductor device in FIG. 5.

### DETAILED DESCRIPTION OF THE INVENTION

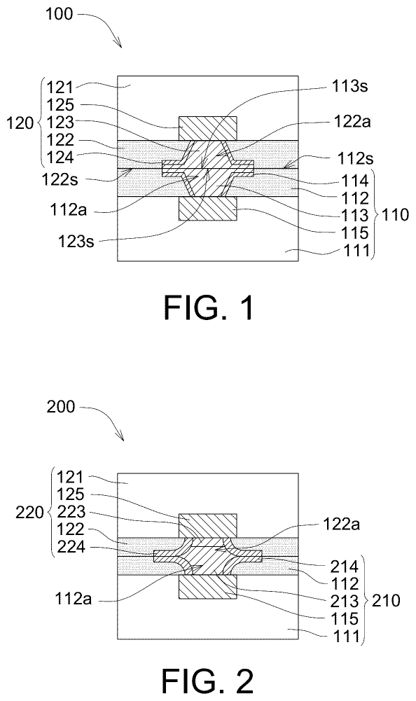

Referring to FIG. 1, FIG. 1 illustrates a schematic diagram of a semiconductor device 100 according to an embodiment of the present invention. The semiconductor device 100 includes a first semiconductor component 110 and a second semiconductor component 120. The first semiconductor component 110 includes a first substrate 111, a first dielectric layer 112, at least one first pad 113, a first barrier layer 114 and at least one first conductive portion 115. The second semiconductor component 120 includes a second substrate 121, a second dielectric layer 122, at least one second pad 123, a second barrier layer 124 and at least one second conductive portion 125.

The first substrate 111 is, for example, a portion of a silicon wafer. The second substrate 121 is, for example, a portion of a silicon wafer.

As illustrated in FIG. 1, the first dielectric layer 112 is disposed over the first substrate 111 and has a first opening 112a. The second dielectric layer 122 is disposed over the second substrate 121 and has a second opening 122a. The first pad 113 disposed in the first opening 112a. The second pad 123 is disposed in the second opening 122a. The first dielectric layer 112 is contact with the second dielectric layer 122, and the first pad 113 is contact with the second pad 123. In an embodiment, the first dielectric layer 112 and the second dielectric layer 122 are formed of insulation material, for example, polyimide, parylene, etc.

As illustrated in FIG. 1, the first dielectric layer 112 has a first dielectric surface 112s, and the first pad 113 does not protrude beyond the first dielectric surface 112s. For example, the first pad 113 has a first pad surface 113s, and the first pad surface 113s and the first dielectric surface 112s are aligned with each other (for example, flush with each other). In addition, the second dielectric layer 122 has a second dielectric surface 122s, and the second pad 123 does not protrude beyond the second dielectric surface 122s. For example, the second pad 123 has a second pad surface 123s, and the second pad surface 123s and the second dielectric surface 122s are aligned with each other (for example, flush with each other). In an embodiment, the first pad 113 and the second pad 123 are formed of metal, for example, gold (Au), copper, etc.

As illustrated in FIG. 1, the first barrier layer 114 is disposed in the first opening 112a and disposed between the first pad 113 and the first dielectric layer 112. The second barrier layer 124 is disposed in the second opening 122a and disposed between the second pad 123 and the second dielectric layer 122. In the present embodiment, the first barrier layer 114 and the second barrier layer 124 are not in contact with each other, but separated from each other by the first pad 113 and the second pad 123. In an embodiment, the first barrier layer 114 and the second barrier layer 124 are formed of metal, for example, titanium (Ti), etc.

In the present embodiment, the first dielectric layer 112 and the second dielectric layer 122 are connected by, for example, a direct bonding technique. The first pad 113 and the second pad 123 are connected by, for example, direct bonding technique.

As illustrated in FIG. 1, the first conductive portion 115 is disposed in the first substrate 111, and the second conductive portion 125 is disposed in the second substrate 121. The first conductive portion 115 and the second conductive portion 125 are electrically connected through the first pad 113 and the second pad 123. In an embodiment, the first conductive portion 115 and the second conductive portion 125 are formed of metal, for example, copper, etc.

Referring to FIG. 2, FIG. 2 illustrates a schematic diagram of a semiconductor device 200 according to another embodiment of the present invention.

As illustrated in FIG. 2, the semiconductor device 200 includes the first semiconductor component 210 and the second semiconductor component 220. The first semiconductor component 210 includes the first substrate 111, the first dielectric layer 112, at least one first pad 213 a first barrier layer 214 and at least one first conductive portion 115. The second semiconductor component 220 includes the second substrate 121, the second dielectric layer 122, at least one second pad 223, a second barrier layer 224 and at least one second conductive portion 125.

As illustrated in FIG. 2, in the present embodiment, a portion of the first pad 213 is disposed in the first opening 112a of the first dielectric layer 112, and another portion of the first pad 213 is disposed in the second opening 122a of the second dielectric layer 122. The entirety of the second pad 223 is disposed in the second opening 122a. The first pad 213 and the second pad 223 are in contact with each other. The first barrier layer 214 is contact with the second barrier layer 224. The first barrier layer 214 and the second barrier layer 224 encapsulate the first pad 213 and the second pad 223. For example, the first barrier layer 214 and the second barrier layer 224 encapsulate the entirety of the pads 213 and 223. A portion of the first pad 213 and the entirety of the first barrier layer 214 are embedded in the first dielectric layer 112, and the entirety of the second pad 223 and the entirety of the second barrier layer 224 are embedded in the second dielectric layer 122.

In an embodiment, the first pad 213 and the second pad 223 are formed of metal, for example, Au, etc., and the first barrier layer 214 and the second barrier layer 224 are formed of metal, for example, Ti, etc.

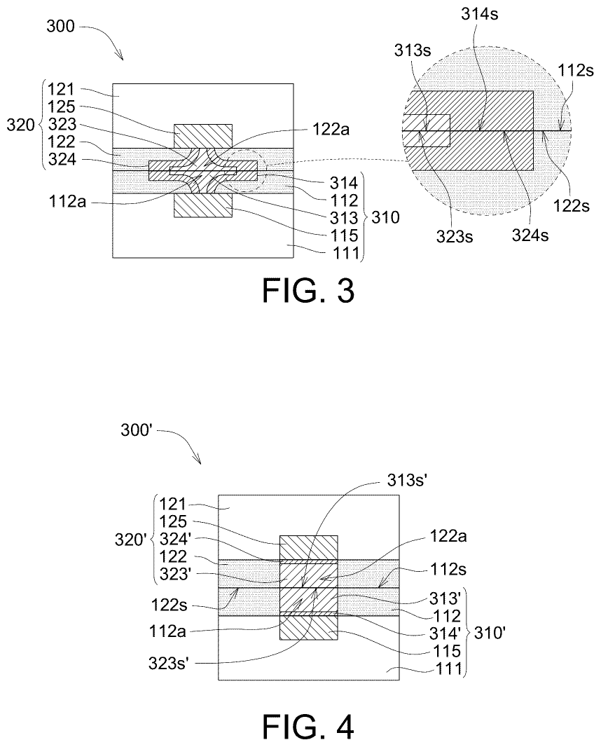

Referring to FIG. 3, FIG. 3 illustrates a schematic diagram of a semiconductor device 300 according to another embodiment of the present invention.

As illustrated in FIG. 3, the semiconductor device 300 includes the first semiconductor component 310 and the second semiconductor component 320. The first semiconductor component 310 includes the first substrate 111, the first dielectric layer 112, at least one first pad 313, a first barrier layer 314 and at least one first conductive portion 115. The second semiconductor component 320 includes the second substrate 121, the second dielectric layer 122, at least one second pad 323, a second barrier layer 324 and at least one second conductive portion 125.

As illustrated in FIG. 3, in the present embodiment, the first barrier layer 314 and the second barrier layer 324 are in contact with each other, the first pad 313 and the second pad 323 are in contact with each other, and the first dielectric layer 112 and the second dielectric layer 122 are in contact with each other. Furthermore, the first dielectric layer 112 has the first dielectric surface 112s, the first pad 313 has a first pad surface 313s, and the first barrier layer 314 has a first barrier surface 314s, wherein the first dielectric surface 112s, the first pad surface 313s and the first barrier surface 314s are aligned with each other (for example, flush with each other). The second dielectric layer 122 has the second dielectric surface 122s, the second pad 323 has a second pad surface 323s, and the second barrier layer 324 has a second barrier surface 324s, wherein the second dielectric surface 122s, the second pad surface 323s and the second barrier surface 324s are aligned with each other (for example, flush with each other).

In an embodiment, the first pad 313 and the second pad 323 are formed of metal, for example, Au, etc., and the first barrier layer 314 and the second barrier layer 324 are formed of metal, for example, Ti, etc.

Referring to FIG. 4, FIG. 4 illustrates a schematic diagram of a semiconductor device 300′ according to another embodiment of the present invention. The semiconductor device 300′ includes a first semiconductor component 310′ and a second semiconductor component 320′. The first semiconductor component 310′ includes the first substrate 111, the first dielectric layer 112, at least one first pad 313′, a first barrier layer 314′ and at least one first conductive portion 115. The second semiconductor component 320′ includes the second substrate 121, the second dielectric layer 122, at least one second pad 323′, a second barrier layer 324′ and at least one second conductive portion 125.

The first substrate 111 is, for example, a portion of a silicon wafer. The second substrate 121 is, for example, a portion of a silicon wafer.

As illustrated in FIG. 4, the first dielectric layer 112 is disposed over the first substrate 111 and has the first opening 112a. The second dielectric layer 122 is disposed over the second substrate 121 and has the second opening 122a. The first pad 313′ disposed in the first opening 112a. The second pad 323′ is disposed in the second opening 122a. The first dielectric layer 112 is contact with the second dielectric layer 122, and the first pad 313′ is contact with the second pad 323′. In an embodiment, the first dielectric layer 112 and the second dielectric layer 122 are formed of insulation material, for example, polyimide, parylene, oxide, etc.

As illustrated in FIG. 4, the first dielectric layer 112 has the first dielectric surface 112s, and the first pad 313′ does not protrude beyond the first dielectric surface 112s. For example, the first pad 313′ has the first pad surface 313s′, and the first pad surface 313s′ and the first dielectric surface 112s are aligned with each other (for example, flush with each other). In addition, the second dielectric layer 122 has the second dielectric surface 122s, and the second pad 323′ does not protrude beyond the second dielectric surface 122s. For example, the second pad 323′ has a second pad surface 323s′, and the second pad surface 323s′ and the second dielectric surface 122s are aligned with each other (for example, flush with each other). In an embodiment, the first pad 313′ and the second pad 323′ are formed of metal, for example, gold (Au), etc.

As illustrated in FIG. 4, the first barrier layer 314′ is disposed in the first opening 112a and disposed between the first pad 313′ and the first conductive portion 115. The second barrier layer 324′ is disposed in the second opening 122a and disposed between the second pad 323′ and the second conductive portion 125. In the present embodiment, the first barrier layer 314′ and the second barrier layer 324′ are not in contact with each other, but separated from each other by the first pad 313′ and the second pad 323′. In an embodiment, the first barrier layer 314′ and the second barrier layer 324′ are formed of metal, for example, titanium (Ti), etc.

In the present embodiment, the first dielectric layer 112 and the second dielectric layer 122 are connected by, for example, a direct bonding technique. The first pad 313′ and the second pad 323′ are connected by, for example, direct bonding technique.

As illustrated in FIG. 4, the first conductive portion 115 is disposed in the first substrate 111, and the second conductive portion 125 is disposed in the second substrate 121. The first conductive portion 115 and the second conductive portion 125 are electrically connected through the first pad 313′ and the second pad 323′. In an embodiment, the first conductive portion 115 and the second conductive portion 125 are formed of metal, for example, copper, etc.

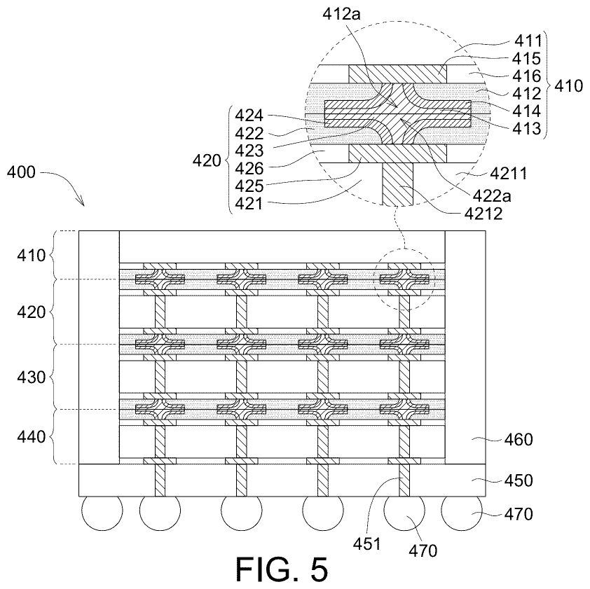

Referring to FIG. 5, FIG. 5 illustrates a schematic diagram of a semiconductor device 400 according to another embodiment of the present invention.

As illustrated in FIG. 5, the semiconductor device 400 includes a first semiconductor component 410, a second semiconductor component 420, a third semiconductor component 430, a fourth semiconductor component 440, a substrate 450, a molding compound 460 and at least one contact 470.

As illustrated in FIG. 5, the first semiconductor component 410 includes a first substrate 411, the first dielectric layer 412, at least one first pad 413, a first barrier layer 414, at least one first conductive portion 415 and a first protective layer 416. The second semiconductor component 420 includes a second substrate 421, a second dielectric layer 422, at least one second pad 423, a second barrier layer 424, at least one second conductive portion 425 and a second protective layer 426.

As illustrated in FIG. 5, the first substrate 411 is, for example, a silicon wafer including at least one integrated circuit which is electrically connected with the first conductive portion 415. The second substrate 421 is, for example, a silicon wafer including at least one integrated circuit which is electrically connected with the second conductive portion 425.

In an embodiment, the first dielectric layer 412 and the second dielectric layer 422 are formed of insulation material, for example, polyimide, parylene, etc. The first pad 413 and the second pad 423 are formed of metal, for example, Au, etc. The first barrier layer 414 and the second barrier layer 424 are formed of metal, for example, Ti, etc. The first conductive portion 415 and the second conductive portion 425 are formed of metal, for example, copper, etc.

In the present embodiment, the first pad 413 and the first barrier layer 414 include the features (for example, material, connection relationship and/or structure, etc.) the same as or similar to that of the first pad 113 and the first barrier layer 114, and the second pad 423 and the second barrier layer 424 include the features the same as or similar to that of the second pad 123 and the second barrier layer 124, as illustrated in FIG. 1. In another embodiment, the first pad 413 and the first barrier layer 414 include the features (for example, material, connection relationship and/or structure, etc.) the same as or similar to that of the first pad 213 and the first barrier layer 214, and the second pad 423 and the second barrier layer 424 include the features the same as or similar to that of the second pad 223 and the second barrier layer 224, as illustrated in FIG. 2. In another embodiment, the first pad 413 and the first barrier layer 414 include the features (for example, material, connection relationship and/or structure, etc.) the same as or similar to that of the first pad 313 and the first barrier layer 314, and the second pad 423 and the second barrier layer 424 include the features the same as or similar to that of the second pad 323 and the second barrier layer 324, as illustrated in FIG. 3.

As illustrated in FIG. 5, the first dielectric layer 412 is disposed over the first substrate 411 and has a first opening 412a. The second dielectric layer 422 is disposed over the second substrate 421 and has a second opening 422a. The first pad 413 disposed in the first opening 412a. The second pad 423 is disposed in the second opening 422a. The first dielectric layer 412 is contact with the second dielectric layer 422, and the first pad 413 is contact with the second pad 423.

As illustrated in FIG. 5, the second substrate 421 of the second semiconductor component 420 includes a base 4211 and at least one conductive via portion 4212, and the conductive via portion 4212 penetrates the base 4211. The base 4211 is, for example, a silicon base, and the conductive via portion 4212 is, for example, TSV (through silicon via). The conductive via portion 4212 connects the second conductive portions 425 which are located at two opposite sides of the second substrate 421. In the present embodiment, the first dielectric layers 412, the first pads 413, the first barrier layer 414 and the first conductive portions 415 are formed on one side of the first substrate 411 of the first semiconductor component 410. The second dielectric layers 422, the second pads 423, the second barrier layers 424, the second conductive portions 425 and the second protective layers 426 may be formed on two opposite sides of the second substrate 421 of the second semiconductor component 420. As a result, the second semiconductor component 420 may connect the semiconductor components 410 and 430 located at two opposite sides of the second semiconductor component 420 respectively. Similarly, the third semiconductor component 430 includes the features the same as or similar to that of the second semiconductor component 420, and the third semiconductor component 430 may connect the semiconductor components 420 and 440 which are located at two opposite sides of the third semiconductor component 430 respectively. The fourth semiconductor component 440 includes the features the same as or similar to that of the first semiconductor component 410, and the fourth semiconductor component 440 may connect the third semiconductor component 430 and the substrate 450 which are located at two opposite sides of the fourth semiconductor component 440 respectively. In addition, the conductive portion of one of the semiconductor components may be electrically connected with the conductive portion of another of the semiconductor components through the conductive via portion.

As illustrated in FIG. 5, the molding compound 460 is disposed on the substrate 450 and encapsulates the first semiconductor component 410, the second semiconductor component 420, the third semiconductor component 430 and the fourth semiconductor component 440. Furthermore, the molding compound 460 covers a portion of an upper surface of the substrate 450 and covers a lateral surface of the first semiconductor component 410, a lateral surface of the second semiconductor component 420, a lateral surface of the third semiconductor component 430 and a lateral surface of the fourth semiconductor component 440. In addition, the molding compound 460 includes materials such as a Novolac-based resin, an epoxy-based resin, a silicone-based resin, or another suitable encapsulant, and may contain suitable fillers such as powdered SiO₂. The molding compound may be formed by using, for example, transfer molding, compression molding, etc.

As illustrated in FIG. 5, the substrate 450 is, for example, an integrated circuit (IC) substrate including at least integrated circuit (IC) or an interposer (for example, a silicon-based interposer), etc. The substrate 450 further includes at least one conductive via portion 451 which may be electrically connected with the fourth semiconductor component 440. In an embodiment the conductive via portion 451 is, for example, TSV.

As illustrated in FIG. 5, the contact 470 may be, for example, solder ball, copper pillar, micro bump, etc. The contacts 470 may be formed on a lower surface of the substrate 450, and the semiconductor device 400 may be electrically connected with a circuit board (not illustrated) through the contacts 470.

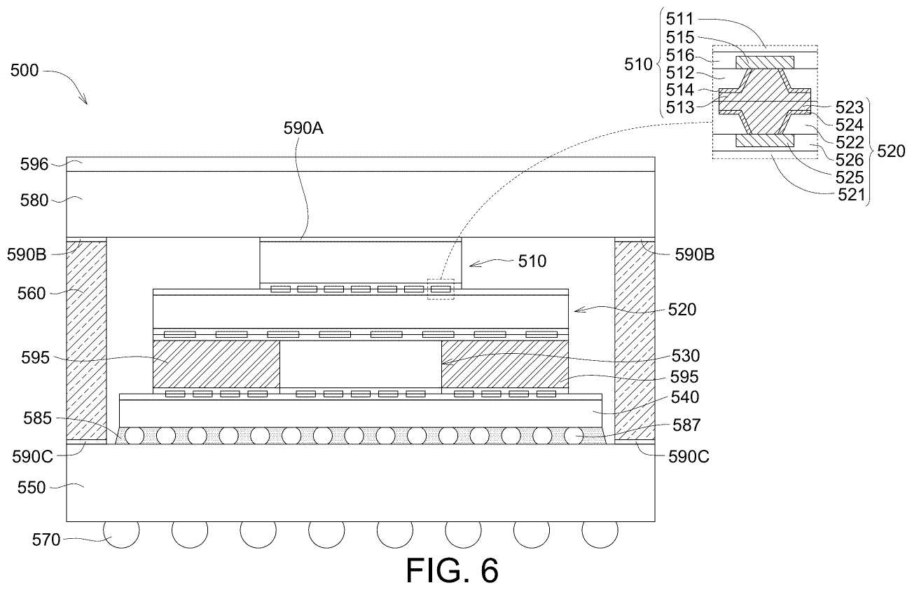

Referring to FIG. 6, FIG. 6 illustrates a schematic diagram of a semiconductor device 500 according to another embodiment of the present invention.

As illustrated in FIG. 6, the semiconductor device 500 includes a first semiconductor component 510, a substrate 520, a third semiconductor component 530, a fourth semiconductor component 540, a substrate 550, at least one connection post 560, at least one contact 570, a cooling component 580, a under filler 585, at least one contact 587, at least one first TIM (thermal interface material) 590A, at least one second TIM 590B, at least one third TIM 590C, at least one spacer 595 and a cold plate 596.

As illustrated in FIG. 6, the first semiconductor component 510 is directly connected with the substrate 520. The substrate 520 directly connects the first semiconductor component 510 with the third semiconductor component 530. The spacers 595 are disposed between the substrate 520 and the fourth semiconductor component 540. The substrate 550 is, for example, a laminate substrate, etc. The substrate 550 further includes at least one conductive via portion (not illustrated) which may be electrically connected with the fourth semiconductor component 540 through at least one contact 587. In an embodiment, the conductive via portion of the substrate 550 is, for example, TSV. The connection post 560 connects the cooling component 580 with the substrate 550. The connection post 560 is, for example, a stiffener ring. The first TIM 590A is disposed between the cooling component 580 and the first semiconductor component 510 and combine the cooling component 580 with the first semiconductor component 510. The second TIM 590B is disposed between the cooling component 580 and the connection post 560 and combine the cooling component 580 with the connection post 560. The third TIM 590C is disposed between the connection post 560 and the substrate 550 and combine the connection post 560 with the substrate 550. The contact 587 is disposed between the fourth semiconductor component 540 and the substrate 550, and electrically connects the fourth semiconductor component 540 and the substrate 550. The under filler 585 is disposed between the fourth semiconductor component 540 and the substrate 550 and encapsulate the contacts 587. The contact 570 may be, for example, solder ball, copper pillar, micro bump, etc. The contacts 570 may be formed on a lower surface of the substrate 550, and the semiconductor device 500 may be electrically connected with a circuit board (not illustrated) through the contacts 570.

As illustrated in FIG. 6, the first semiconductor component 510 includes a first substrate 511, a first dielectric layer 512, at least one first pad 513, a first barrier layer 514, at least one first conductive portion 515 and at least one first protective layer 516. The substrate 520 includes a second substrate 521, a second dielectric layer 522, at least one second pad 523, a second barrier layer 524, at least one second conductive portion 525 and at least one second protective layer 526.

As illustrated in FIG. 6, the first substrate 511 is, for example, a silicon wafer including at least one circuit which is electrically connected with the first conductive portion 515. The second substrate 521 is, for example, a silicon wafer including at least one circuit which is electrically connected with the second conductive portion 525.

In an embodiment, the first dielectric layer 512 and the second dielectric layer 522 are formed of insulation material, for example, polyimide, parylene, etc. The first pad 513 and the second pad 523 are formed of metal, for example, Au, etc. The first barrier layer 514 and the second barrier layer 524 are formed of metal, for example, Ti, etc. The first conductive portion 515 and the second conductive portion 525 are formed of metal, for example, copper, etc. The first conductive portion 515 is formed in the first protective layer 516, and the second conductive portion 525 is formed in the second protective layer 526.

In the present embodiment, the first pad 513 and the first barrier layer 514 include the features (for example, material, connection relationship and/or structure, etc.) the same as or similar to that of the first pad 113 and the first barrier layer 114, and the second pad 523 and the second barrier layer 524 include the features the same as or similar to that of the second pad 123 and the second barrier layer 124, as illustrated in FIG. 1. In another embodiment, the first pad 513 and the first barrier layer 514 include the features (for example, material, connection relationship and/or structure, etc.) the same as or similar to that of the first pad 213 and the first barrier layer 214, and the second pad 523 and the second barrier layer 524 include the features the same as or similar to that of the second pad 223 and the second barrier layer 224, as illustrated in FIG. 2. In another embodiment, the first pad 513 and the first barrier layer 514 include the features (for example, material, connection relationship and/or structure, etc.) the same as or similar to that of the first pad 313 and the first barrier layer 314, and the second pad 523 and the second barrier layer 524 include the features the same as or similar to that of the second pad 323 and the second barrier layer 324 as illustrated in FIG. 3.

In the present embodiment, the first dielectric layers 512, the first pads 513, the first barrier layer 514 and the first conductive portions 515 are formed on one side of the first substrate 511. The second dielectric layers 522, the second pads 523, the second barrier layers 524, the second conductive portions 525 and the second protective layers 526 may be formed on two opposite sides of the second substrate 521. As a result, the substrate 520 may connect the semiconductor components 510 and 530 located at two opposite sides of the substrate 520 respectively. In addition, the substrate 520 may be LTC interposer. Similarly, the third semiconductor component 530 includes the features the same as or similar to that of the substrate 520 or the semiconductor component 510, and the third semiconductor component 530 may connect the substrate 520 and the fourth semiconductor component and 540 which are located at two opposite sides of the third semiconductor component 530 respectively. The fourth semiconductor component 540 includes the features the same as or similar to that of the first semiconductor component 510, and the fourth semiconductor component 540 may connect the third semiconductor component 530 and the substrate 550 which are located at two opposite sides of the fourth semiconductor component 540 respectively. In addition, the conductive portion of one of the semiconductor components may be electrically connected with the conductive portion of another of the semiconductor components through at least one conductive via portion.

The cold plate 596 is disposed on the cooling component 580 for carrying the heat out of the semiconductor device 500. The cold plate 596 is, for example, a liquid cooling-type heat dissipation device.

As disclosed above, the basic structure or the building block for flip chip bonding disclosed herein consists of: (a). ultra-thin soft metal pad (e.g., Au)/barrier (e.g., Ti) bonding pads (a few μm to 100 nm thick) created on; (b). an ultra-thin and compliant conformal passivation (e.g., polyimide or parylene) layer (a few μm to 100 nm) atop; (c). an ultra-thin active IC which is planarized to a root-mean-square roughness of a few nanometers (nm); and (d). whose passivation layer and bonding pads on the passivation layer can be “concurrently” modified and activated by a suitable plasma (e.g., water vapor plasma) prior to “concurrent” direct passivation and soft metal bonding.

Soft metals including Au here are those which are malleable and can be cut and easy to dent, work, or cut without shattering. Softness of the soft metals can be attributed to its weak metallic bonding in them due to large sizes of the atoms. According to the Mohs hardness scale, soft metals include: Pb, Au, Ag, Sn, Zn and Th. Soft metals can also include solders containing these substances. Annealing can be used to modify metal properties after deposition through the mechanisms of re-crystallization, stress reduction and/or diffusion of alloys.

Candidates of thin passivation layer (or dielectric layer) material include polyimide (e.g., fully cured PMDA-ODA polyimide), parylene and other suitable materials that are amenable to thin film processing and that can be activated by plasma concurrently with the bonding pads, whereas barrier layer candidates include Ti, TiW, Ta, TaN, Cr, phased CrCu, Ti/Ni—V, TiW—Ni—V, Ti/Ni, Ti—W/Ni and their combinations. Polyimide is among the most commonly used passivation in wafer BEOL and the dielectric used in wafer-level packaging including fan-in, fan-out, 2.5D IC and 3D IC. Polyimide and parylene are among the materials that can be activated simultaneously with Au bonding pads.

Metal of conductive portion such as the aforementioned soft metal and the barrier layers can be deposited by physical vapor deposition (covering e-beam evaporation, sputtering and pulsed laser deposition). This includes Au, Ti, Cr, Ni, Pt, Pd and Ta. Methods to deposit Au include evaporation, sputtering and plated covering both electrolytic and electrodeless immersion.

A suitable plasma such as water vapor plasma enhances both the polyimide (or parylene; the passivation layer)-to-polyimide adhesion and promotes self-alignment between the two adjoining polymer layers, while also simultaneously enhancing gold-to-gold bonding of two adjacent ICs (or an IC and an adjacent component such as an interposer used in 2.5D and 3D IC packaging) during low-temperature (<200° C.) thermo-compression bonding.

The disclosed structures and processes invoke flip-chip-like assembly involving ultra-thin bonding/barrier layers as opposed to state-of-the-art flip chip assembly based on much thicker copper pillar micro-bumps (≥˜25 μm in thickness) with a solder tip where:
the latter requires the application of (a). a flux for the solder; (b). a flux cleaning step; and (c). a non-conductive paste (NCP) to fill the spaces between micro-bumps, and
the former is self-aligning and does not require (a) to (c) as the former leaves no space between mating surface-activated polyimide layers and Au pads following thermo-compression bonding due to the thinness of the soft metal bond pads, the compliance of the polymer passivation, the polymer-to-polymer bonding forces and the bonding force exerted during low-temperature (≤200° C.) thermo-compression bonding. Following water vapor plasma treatment, it has been demonstrated that the polyimide-to-polyimide interfacial adhesion strength, for instance, exceeds the cohesive strength of the applied polyimide layer. Excellent bonding quality has also been achieved at the gold-to-gold interface.

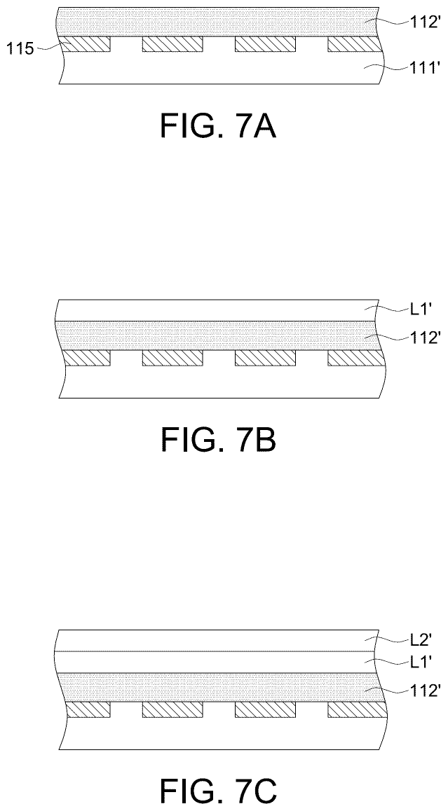

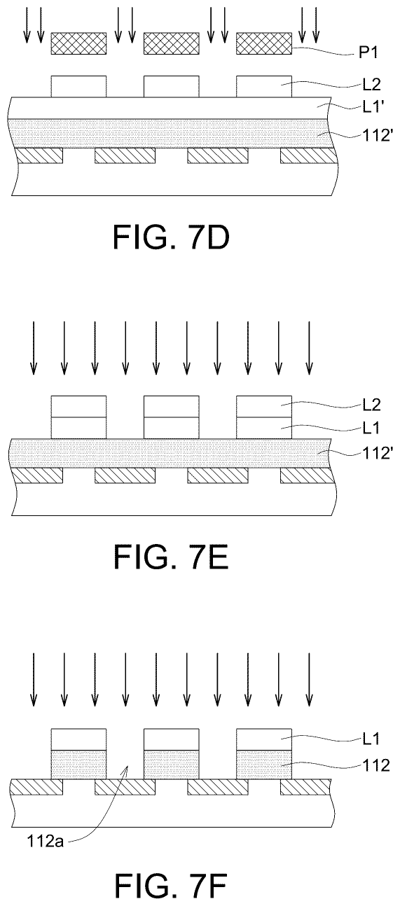

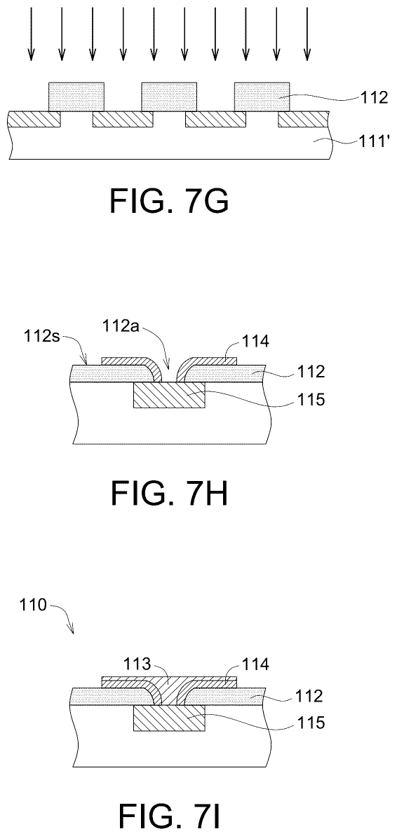

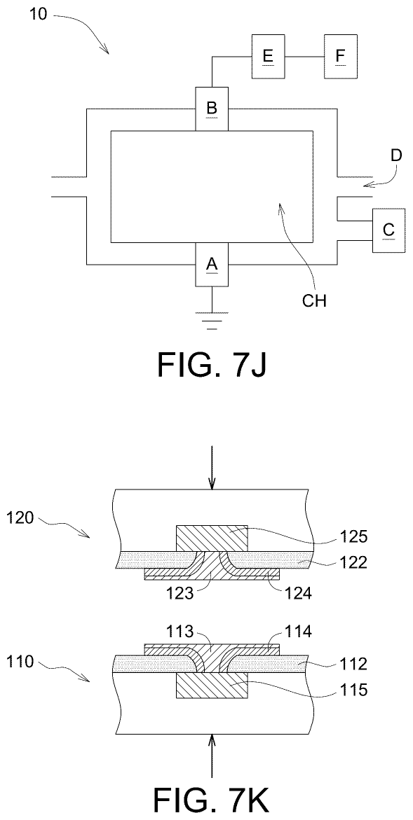

Referring to FIGS. 7A to 7K, FIGS. 7A to 7K illustrate schematic diagrams of a manufacturing method of the semiconductor device 100 in FIG. 1.

As illustrated in FIG. 7A, a dielectric layer material 112′ is formed on the first substrate 111′ by using, for example, deposition, etc. The first substrate 111′ is, for example, a silicon wafer. The dielectric layer material 112′ is formed of insulation material, for example, polyimide, parylene, etc. The first substrate 111′ may include at least one integrated circuit which is electrically connected with the first conductive portion 115 formed in the first substrate 111′.

As illustrated in FIG. 7B, a metal layer L1′ is formed on the dielectric layer material 112′. The metal layer L1′ is, for example, aluminum layer.

As illustrated in FIG. 7C, a photoresist L2′ is formed on the metal layer L1′ by using, for example, deposition.

As illustrated in FIG. 7D, the photoresist L2′ is patterned to form a patterned photoresist L2 through a mask P1 by using, for example, photolithography, etc.

As illustrated in FIG. 7E, the metal layer L1′ is patterned to form a patterned metal layer L1 through the patterned photoresist L2 by using, for example, dry etching (for example, HBr and Cl₂ plasma), etc.

As illustrated in FIG. 7F, the dielectric layer material 112′ is patterned to form the first dielectric layer 112 through the patterned metal layer L1 and the patterned photoresist L2 by using, for example, dry etching (for example, O₂ plasma), etc. The first dielectric layer 112 has at least one first opening 112a. Then, the patterned photoresist L2 may be removed by using, for example, stripping.

As illustrated in FIG. 7G, the patterned metal layer L1 in FIG. 7F is removed by using, for example, dry etching (for example, HBr and Cl₂ plasma), etc.

As illustrated in FIG. 7H, the first barrier layer 114 is formed in the first opening 112a and on the first dielectric surface 112s of the first dielectric layer 112. The first barrier layer 114 extends to the first conductive portion 115 and exposes the first conductive portion 115.

As illustrated in FIG. 7I, the first pad 113 is formed in the first opening 112a and on the first barrier layer 114 to form the first semiconductor component 110. The first pad 113 extends to the first conductive portion 115 and covers the first conductive portion 115. In the present embodiment, the first pad 113 may cover most or the entirety of the upper surface of the first barrier layer 114.

As illustrated in FIG. 7J, a plasma apparatus (plasma system) 10 is provided. Then, as illustrated in FIG. 7K, the first dielectric layer 112 and the first pad 113 of the first semiconductor component 110 in FIG. 7I is activated by using, for example, plasma. The second semiconductor component 120 may be formed by the method the same as or similar to that of the first semiconductor component 110.

The schematic of an exemplary water vapor plasma system used in enhancing polyimide-to-polyimide adhesion may be seen in FIG. 7J. The plasma system consists of a stainless-steel vacuum chamber CH with parallel plate electrodes. Prior to processing, the chamber was evacuated to a base pressure in the 10⁻⁷ torr range using a 500 L/s turbo molecular pump. The plasma was generated between a grounded electrode (A) and an RF-powered electrode (B) attached to an 800 W, 13.56 MHz generator (F), through an automatic impedance matching network (E). The electrodes are 10 inches in diameter and separated by a 5 inches gap. During typical operation, 50 W of RF power was applied to the system. Samples were placed on the grounded electrode (A) and both electrodes had graphite cover plates. During processing, the system was pumped using a 30 CMH mechanical pump, and the pressure was monitored with a capacitance manometer (C). Water vapor was introduced into the chamber at point (D) using a heated liquid source (50° C.-100° C.) and a condensable vapor mass flow controller. All vapor transfer lines approaching the chamber were maintained at 100° C., and a refrigerated re-circulator was used to maintain both electrodes at 25° C. Alternatively, one can also use Ar/water vapor plasma to pre-treat the mating surfaces wherein Ar plasma primarily causes physical etching, whereas water vapor plasma induces both chemical activation and physical etching while preventing oxidation. As in the case of polyimide surface treatment by water vapor plasma, a parylene film that has undergone water vapor plasma treatment (following steam heating as needed) can be directly bonded at a low temperature below paryelne's glass transition temperature (e.g., 90° C. for paryalene C) with another parylene after going through the identical water vapor plasma treatment. Water vapor plasma hydrophilize parylene surfaces and facilitate direct parylene-to-parylene bonding. Compared to polyimide for passivation, parylene can be a better and extremely effective moisture and chemical barrier at ultra-thin film thicknesses.

As illustrated in FIG. 7K, the second semiconductor component 120 and the first semiconductor component 110 may be directly connected by, for example, a direct bonding technique. The bonding process may be performed in the low-pressure vacuum environment. After bonding, the first dielectric layer 112 is contact with the second dielectric layer 122, the first pad 113 is contact with the second pad 123, and the first barrier layer 114 is contact with the second barrier layer 124.

Then, the bonded first semiconductor component 110 and second semiconductor component 120 may be singulated to form the semiconductor device 100 in FIG. 1 by using, for example, sawing.

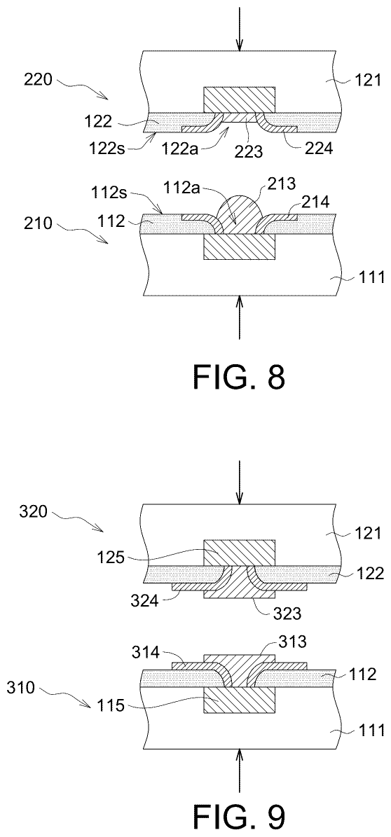

Referring to FIG. 8, FIG. 8 illustrates a schematic diagram of a process of a manufacturing method of the semiconductor device 200 in FIG. 2. The manufacturing method of the semiconductor device 200 includes the process the same as or similar to that of the semiconductor device 100, and at least one difference is that a portion of the first pad 213 is disposed in the first opening 112a, and another portion of the first pad 213 protrudes relative to the first dielectric surface 112s of the first dielectric layer 112, while the second pad 223 is disposed in a portion of the second opening 122a of the second dielectric layer 122. After bonding, a portion of the first pad 213 is located within the second opening 122a of the second dielectric layer 122, the first dielectric layer 112 is contact with the second dielectric layer 122, the first pad 213 is contact with the second pad 223, and the first barrier layer 214 is contact with the second barrier layer 224. Then, the boned first semiconductor component 210 and second semiconductor component 220 may be singulated to form the semiconductor device 200 in FIG. 2 by using, for example, sawing.

Referring to FIG. 9, FIG. 9 illustrates a schematic diagram of a process of a manufacturing method of the semiconductor device 300 in FIG. 3. The manufacturing method of the semiconductor device 300 includes the process the same as or similar to that of the semiconductor device 100, and at least one difference is that a portion of the first pad 313 covers a portion of the upper surface of the first barrier layer 314, and a portion of the second pad 323 covers a portion of the upper surface of the second barrier layer 324. After bonding, the first dielectric layer 112 is contact with the second dielectric layer 122, the first pad 313 is contact with the second pad 323, and the first barrier layer 314 is contact with the second barrier layer 324. Then, the boned first semiconductor component 310 and second semiconductor component 320 may be singulated to form the semiconductor device 300 in FIG. 3 by using, for example, sawing.

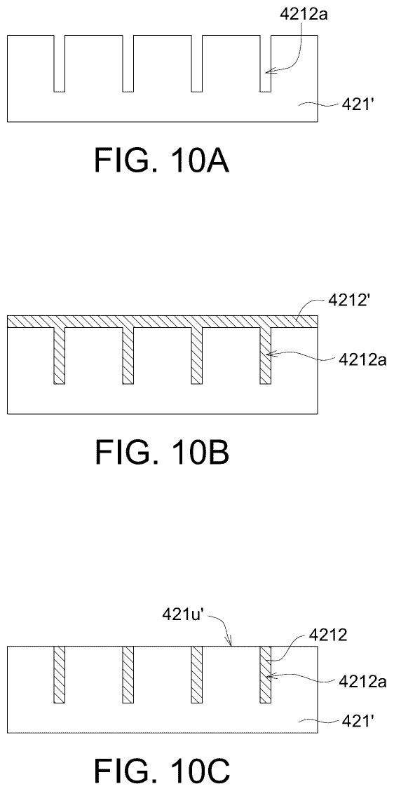

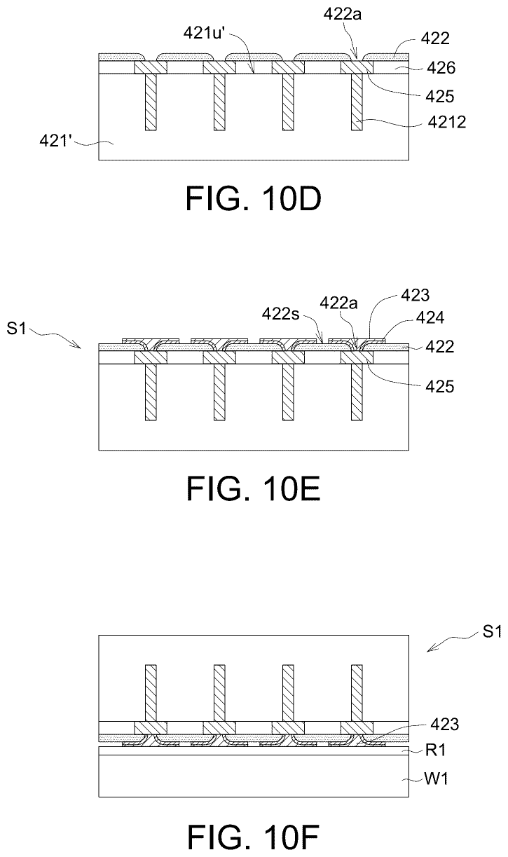

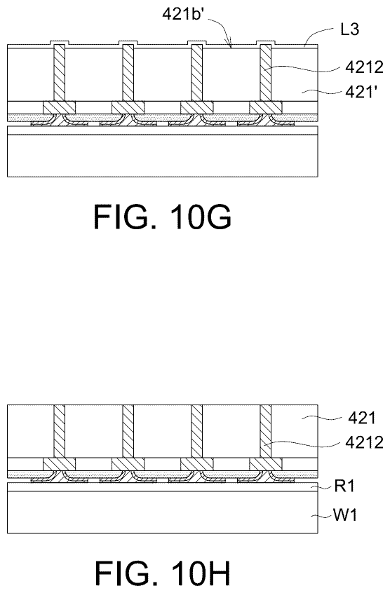

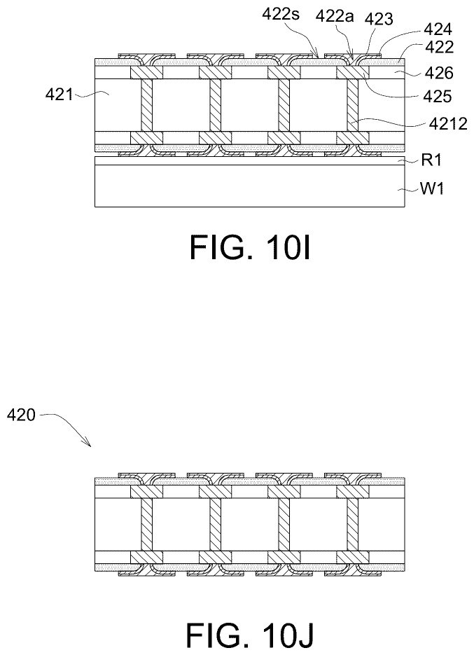

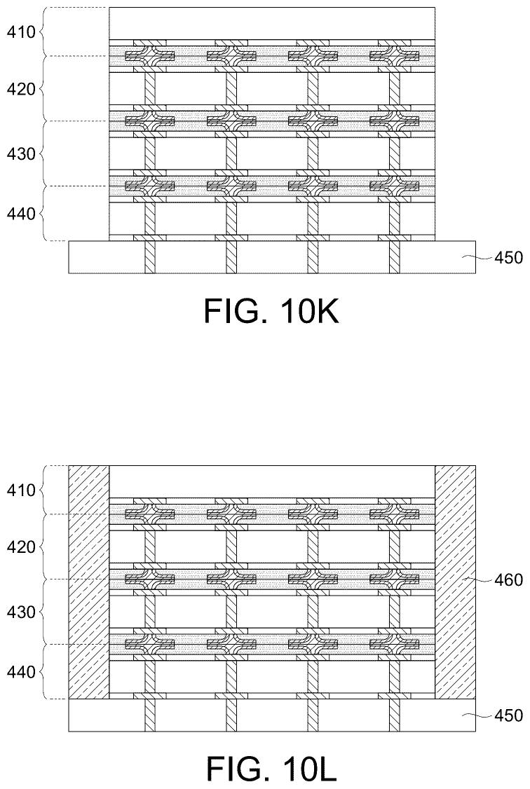

Referring to FIGS. 10A to 10L, FIGS. 10A to 10L illustrate schematic diagrams of a manufacturing method of the semiconductor device 400 in FIG. 5.

As illustrated in FIG. 10A, a base 421′ is patterned by using, for example, etching. The base 421′ is, for example, a silicon wafer, and has at least one hole 4212a. The hole 4212a is, for example, TSV.

As illustrated in FIG. 10B, a conductive layer 4212′ within the holes 4212a and on an upper surface of the base 421′ is formed by using, for example, deposition, etc.

As illustrated in FIG. 10C, a portion of the conductive layer 4212′ in FIG. 10B is removed to form at least one conductive via portion 4212 within the hole 4212a by using, for example, CMP. The base 421′ in FIG. 10C has a front-side surface 421u′.

As illustrated in FIG. 10D, the second protective layer 426 over the front-side surface 421u′ of the base 421′ is formed by using, for example, deposition, photolithography, etc. The second protective layer 426 has at least one hole exposing the conductive via portion 4212. Then, at least one second conductive portion 425 connected with the conductive via portion 4212 is formed in the hole of the second protective layer 426 by using, for example, electroplate, photolithography, CMP, etc. Then, the second dielectric layer 422 is formed on the second protective layer 426 by using, for example, deposition, photolithography, etc., wherein the second dielectric layer 422 has at least one second opening 422a exposing the second conductive portion 425.

As illustrated in FIG. 10E, the second barrier layer 424 in the second opening 422a of the second dielectric layer 422 and on an upper surface 422s of the second dielectric layer 422 is formed by using, for example, electroplating, photolithography, etc. Then, the second pad 423 connected with the second conductive portion 425 is formed on the second barrier layer 424 by using, for example, electroplating, photolithography, etc.

As illustrated in FIG. 10F, the structure S1 in FIG. 10E is inverted and then disposed on a release film R1 disposed on a temporary wafer W1. The second pads 423 face down to be adhered to the release film R1.

As illustrated in FIG. 10G, the base 421′ is thinned to form the base 421 by using, for example, CMP. After CMP, the conductive via portion 4212 protrudes relative to a backside surface 421b′ of the base 421′. Then, a backside passivation L3 covering the backside surface 421b′ of the base 421′ and the conductive via portion 4212 is formed by using, for example, deposition, etc.

As illustrated in FIG. 10H, the backside passivation L3 is planarized to expose the conductive via portion 4212 by using, for example, CMP.

As illustrated in FIG. 10I, the second protective layer 426 over the base 421 is formed by using, for example, photolithography, etc. The second protective layer 426 has at least one hole exposing the conductive via portion 4212. Then, at least one second conductive portion 425 connected with the hole of the second protective layer 426 is formed by using, for example, electroplate, photolithography, etc. Then, the second dielectric layer 422 is formed on the second protective layer 426 by using, for example, deposition, photolithography, etc., wherein the second dielectric layer 422 has at least one second opening 422a exposing the second conductive portion 425. Then, the second barrier layer 424 in the second opening 422a of the second dielectric layer 422 and on the upper surface 422s of the second dielectric layer 422 is formed by using, for example, electroplating, photolithography, etc. Then, the second pad 423 connected with the second conductive portion 425 is formed on the second barrier layer 424.

As illustrated in FIG. 10J, the temporary wafer W1 with the release film R1 is removed to form the second semiconductor component 420.

As illustrated in FIG. 10K, the fourth semiconductor component 440 is disposed on the substrate 450, the third semiconductor component 430 is disposed on the fourth semiconductor component 440, the second semiconductor component 420 is disposed on the third semiconductor component 430, the first semiconductor component 410 is disposed on the second semiconductor component 420. The fourth semiconductor component 440, the third semiconductor component 430 and the first semiconductor component 410 may be manufactured by the processes same as or similar to that of the second semiconductor component 420. Alternatively, the second semiconductor component 420 may be manufactured by the processes same as or similar to the third semiconductor component 430, and/or the first semiconductor component 410 may be manufactured by the processes same as or similar to the fourth semiconductor component 440.

As illustrated in FIG. 10L, the molding compound 460 covering a portion of the upper surface of the substrate 450 and covering a lateral surface of the first semiconductor component 410, a lateral surface of the second semiconductor component 420, a lateral surface of the third semiconductor component 430 and a lateral surface of the fourth semiconductor component 440 is formed.

Then, the contacts 470 are formed on a lower surface of the substrate 450 to form the semiconductor device 400 in FIG. 5. The contact 470 may be, for example, solder ball, copper pillar, micro bump, etc.

As disclosed above, the innovative structures and corresponding processes are disclosed to assemble novel ultra-thin, thermally enhanced 2.5D IC and 3D IC packages involving ultra-thin advanced ICs (e.g., processor and memory; thinner than 30 μm) containing soft metal bond pads at ≤20 μm pitches, far below the smallest pitch of 40 μm used in high-volume flip chip production today on high-end processors. These liquid immersion cooled 2.5D and 3D structures provide far-higher function densities per unit volume and far-higher bandwidths while enabling far-higher processor power (up to 1500 W/chip or higher versus 700 W/chip for nVidia's direct-to-chip liquid cooled H100 GPU, the world's most powerful GPU today) compared to mainstream 2.5D and 3D packages.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A semiconductor device, comprising:
a first semiconductor component, comprising:
a first substrate;
a first dielectric layer over the first substrate and having a first opening; and
a first pad in the first opening;
a second semiconductor component, comprising:
a second substrate; and
a second dielectric layer over the second substrate and having a second opening;
a second pad in the second opening;
wherein the first dielectric layer is contact with the second dielectric layer, and the first pad is contact with the second pad.

2. The semiconductor device according to claim 1, wherein the first dielectric layer has a first dielectric surface, and the first pad does not protrude beyond the first dielectric surface.

3. The semiconductor device according to claim 1, wherein the second dielectric layer has a second dielectric surface, and the second pad does not protrude beyond the second dielectric surface.

4. The semiconductor device according to claim 1, wherein the first dielectric layer has a first dielectric surface, the first pad has a first pad surface, and the first dielectric surface and the first pad surface are flushed with each other.

5. The semiconductor device according to claim 1, wherein the second dielectric layer has a second dielectric surface, the second pad has a second pad surface, and the second dielectric surface and the second pad surface are flushed with each other.

6. The semiconductor device according to claim 1, wherein the first semiconductor component further comprises a first barrier layer in the first opening and disposed between the first pad and the first dielectric layer; the second semiconductor component further comprises a second barrier layer in the second opening and disposed between the second pad and the second dielectric layer; the first barrier layer is contact with the second barrier layer.

7. The semiconductor device according to claim 6, wherein the first barrier layer and the second barrier layer encapsulate the first pad and the second pad.

8. The semiconductor device according to claim 6, wherein the first pad and the first barrier layer are embedded in the first dielectric layer, and the second pad and the second barrier layer are embedded in the second dielectric layer.

9. The semiconductor device according to claim 1, wherein the first pad and the second pad are formed of gold.

10. A manufacturing method for a semiconductor device, comprising:
providing a first semiconductor component, wherein the first semiconductor component comprises a first substrate, a first dielectric layer and a first pad, the first dielectric layer is disposed over the first substrate and has a first opening, and the first pad is disposed in the first opening;
providing a second semiconductor component, wherein the second semiconductor component comprises a second substrate, a second dielectric layer and a second pad, the second dielectric layer is disposed over the second substrate and has a second opening, and the second pad is disposed in the second opening;
activating the first dielectric layer and the first pad of the first semiconductor component and the second dielectric layer and the second pad of the second semiconductor component; and
connecting the first semiconductor component with the second semiconductor component, wherein the first dielectric layer is contact with the second dielectric layer, and the first pad is contact with the second pad.

11. The manufacturing method according to claim 10, wherein activating the first dielectric layer and the first pad of the first semiconductor component and the second dielectric layer and the second pad of the second semiconductor component is performed by wafer vapor plasma.

12. The manufacturing method according to claim 10, wherein in providing the first semiconductor component, the first dielectric layer has a first dielectric surface, and the first pad protrudes beyond the first dielectric surface.

13. The manufacturing method according to claim 10, wherein in providing the second semiconductor component, the second dielectric layer has a second dielectric surface, and the second pad protrudes beyond the second dielectric surface.

14. The manufacturing method according to claim 10, wherein in connecting the first semiconductor component with the second semiconductor component, the first dielectric layer has a first dielectric surface, and the first pad does not protrude beyond the first dielectric surface.

15. The manufacturing method according to claim 10, wherein in connecting the first semiconductor component with the second semiconductor component, the second dielectric layer has a second dielectric surface, and the second pad does not protrude beyond the second dielectric surface.

16. The manufacturing method according to claim 10, wherein in connecting the first semiconductor component with the second semiconductor component, the first dielectric layer has a first dielectric surface, the first pad has a first pad surface, and the first dielectric surface and the first pad surface are flushed with each other.

17. The manufacturing method according to claim 10, wherein in connecting the first semiconductor component with the second semiconductor component, the second dielectric layer has a second dielectric surface, the second pad has a second pad surface, and the second dielectric surface and the second pad surface are flushed with each other.

18. The manufacturing method according to claim 10, wherein in connecting the first semiconductor component with the second semiconductor component, the first semiconductor component further comprises a first barrier layer in the first opening and disposed between the first pad and the first dielectric layer; the second semiconductor component further comprises a second barrier layer in the second opening and disposed between the second pad and the second dielectric layer; the first barrier layer is contact with the second barrier layer.
